(19) United States
(12) Patent Application Publication
(10) Pub. No.: US 2011/0316138 A1
(43) Pub. Date: Dec. 29, 2011

(54) HIGH FREQUENCY FAST RECOVERY DIODE

(75) Inventors: Quanya Lv, Jiangsu (CN); Yunfeng Chen, Jiangsu (CN); Jiming Yang, Jiangsu (CN)

(73) Assignee: CHANGZHOU GIANTION PHOTOELECTRICITY INDUSTRY DEVELOPMENT CO., LTD., Changzhou City (CN)

(21) Appl. No.: 13/255,458

(22) PCT Filed: Jul. 16, 2010
(86) PCT No.: PCT/CN10/75224

§ 371 Date: Sep. 8, 2011

(30) Foreign Application Priority Data
Aug. 11, 2009 (CN) 200910183195.7

(51) Int. Cl. H01L 23/48

(52) U.S. Cl. 257/690; 257/E23.01

(57) ABSTRACT

A high-frequency fast recovery diode that includes a diode chip set, solder lugs, lead wires, lead terminals, a silicone coating layer and a plastic package body. The diode chip set includes n-diode chips arranged in the same polarity order sequentially, a part of the n-diode chips can be fast recovery diode chips and others can be conventional. Solder lugs are placed on both sides of, and connected with, each diode chip. Lead wires are connected with the solder lugs on the ends of the diode chip set, respectively. The silicone coating layer is provided around the diode chip set and the lugs. The plastic package body is provided around the lead terminals and the silicone coating layer. The shape of the plastic package body can be a cylindrical or square column. The reverse recovery time of the high-frequency fast recovery diode can be shortened, and the voltage resistance performance improved.

### PRIORITY CLAIM

The present application is a National Phase entry of PCT Application No. PCT/CN2010/075224, filed Jul. 16, 2010, which claims priority from Chinese Application 200910183195.7, filed Aug. 11, 2009, the disclosures of which are hereby incorporated by reference herein in their entirety.

### FIELD OF THE INVENTION

The present invention relates to a high-frequency diode in the field of semiconductor devices, in particular to the structure of a high-frequency fast recovery diode with multiple crystal grain.

### BACKGROUND OF THE INVENTION

Nowadays, electronic technology has been widely applied in all fields of the national economy, and is developing rapidly. Electronic technology has characteristics such as easy control, high efficiency, and energy conservation, and is regarded as one of key technologies by the state. Electronic technology develops towards the trend of high voltage, high capacity, high speed, high frequency, modularity, and intelligence. High-frequency fast recovery diodes are new semiconductor devices that have emerged in recent years, and have advantages such as good switching characteristics, short reverse-recovery time, high forward current, small size, and easy installation, etc. They have been widely used as high-frequency and large-current freewheeling diodes or rectifying diodes in switching power supply, pulse-width modulators, uninterruptible power supply, frequency controllers for AC motors, and high-frequency heaters, etc., and are electric and electronic semiconductor devices that have great growth potential.

All conventional high-frequency fast recovery diodes are composed of multiple fast recovery diode chips, which have short reverse recovery time and high voltage resistance; however, these chips are expensive and in short supply, and sometimes have to be imported. There is an urgent need to provide high-frequency fast recovery diodes that not only have short reverse recovery time and high voltage resistance, but also are cheap and widely available and suitable for mass production.

### SUMMARY OF THE INVENTION

The object of the present invention is to provide a high-frequency fast recovery diode, which not only has short reverse recovery time and high voltage resistance, but also can be produced at a lower cost and is suitable for mass production.

To achieve the above object, the technical scheme of the present invention is: a high-frequency fast recovery diode, comprising a diode chipset, solder lugs, lead wires, lead terminals, cladding, and plastic package. The diode chipset comprises n diode chips aligned by equidirectional polarity, each side of the diode chipset is arranged with a solder lug and the diode chipset is connected with the solder lugs; the end faces of lead terminals of two diode lead wires are connected with the solder lugs on both sides of the diode chipset, respectively; the diode chipset and solder lugs are enclosed by the cladding, and the lead terminals and cladding are packed by the plastic package. In the n diode chips, 1, 2, or n−1 diode chip(s) is(are) fast recovery diode chips, while the rest diode chip(s) is(are) conventional rectifying diode chips.

Said diode chipset may comprise one fast recovery diode chip and two conventional rectifying diode chips.

Said plastic package has cylindrical or square column shape, said cladding is a silicone cladding, and the plastic package is an epoxy resin package.

Compared to the prior art, the present invention has the following advantages: the high-frequency fast recovery diode is formed by cascading several diode chips, and the charge/discharge time thereof is the sum of reciprocal values of charge/discharge time of each diode chip. The charge/discharge time of fast recovery diode chips is shorter than that of conventional rectifying diode chips; the charge/discharge time of the conventional high-frequency fast recovery diode is the sum of the reciprocal values of charge/discharge time of each chip, thus it is certainly longer than the charge/discharge time of a high-frequency fast recovery diode in which some fast recovery diode chips are replaced with conventional rectifying diode chips. Therefore, compared with conventional high-frequency fast recovery diodes, the improved high-frequency fast recovery diode has shorter reverse recovery time characteristic and can shorten the reverse recovery time. In addition, the voltage resistance of a high-frequency fast recovery diode is the sum of voltage resistance of each diode chip; conventional rectifying diode chips with higher voltage resistance can be obtained at the same price, thus some fast recovery diode chips in the high-frequency fast recovery diode can be replaced with conventional rectifying diode chips with higher voltage resistance; in this way, the voltage resistance of the high-frequency fast recovery diode can be improved. Since the price of a conventional rectifying diode chip is only ⅔ of the price of a fast recovery diode chip, the production cost of the high-frequency fast recovery diode in the present invention can be reduced. Moreover, conventional rectifying diode chips are widely available, and can be processed by the diode manufacturer, and therefore are suitable for mass production.

### BRIEF DESCRIPTION OF THE DRAWINGS

FIG. 1 is a structural representation of embodiment 1 according to the present invention;

FIG. 2 is a structural representation of embodiment 2 according to the present invention.

### DETAILED DESCRIPTION

Hereinafter the present invention will be described in further details in the embodiments, with reference to the accompanying drawings.

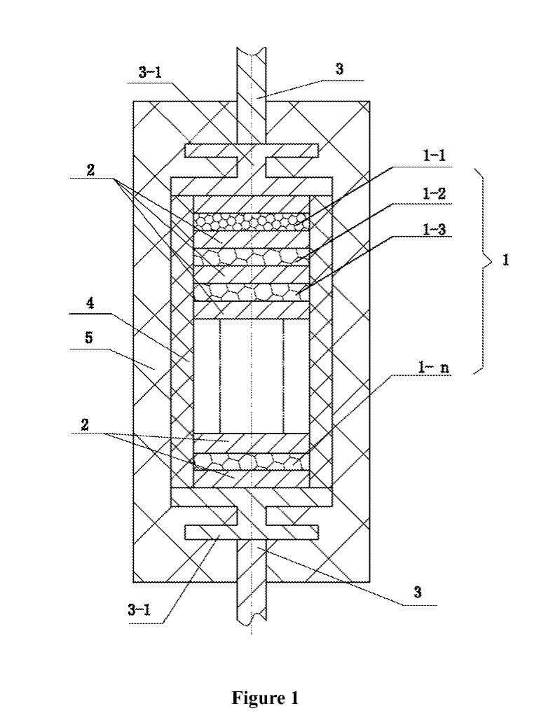

FIG. 1 is a structural representation of embodiment 1 according to the present invention. As shown in FIG. 1, the high-frequency fast recovery diode comprises a diode chipset 1, solder lugs 2, lead wires 3, lead terminals 3-1, a cladding 4, and a plastic package 5; the diode chipset 1 comprises n diode chips 1-1, 1-2, 1-3, . . . , 1-n, which are aligned by equidirectional polarity; both sides of each diode chip 1-1, 1-2, 1-3, . . . , 1-n are arranged with a solder lug 2 and the diode chip is connected with the solder lug 2; the end faces of lead terminals 3-1 of two diode lead wires 3 are connected with the solder lugs 2 on both sides of the diode chipset 1 respectively; the diode chipset 1 and solder lugs 2 are enclosed by the cladding 4, and the two lead terminals 3-1 and cladding 4 are packed by the plastic package 5; in said n diode chips 1-1, 1-2, 1-3, . . . , 1-n, 1, 2, . . . , or n-1 diode chips are fast recovery diode chips, while the rest of the diode chips are conventional rectifying diode chips. Said plastic package 5 has a cylindrical column shape. Said cladding 4 is a silicone cladding, and the plastic package 5 is an epoxy resin package.

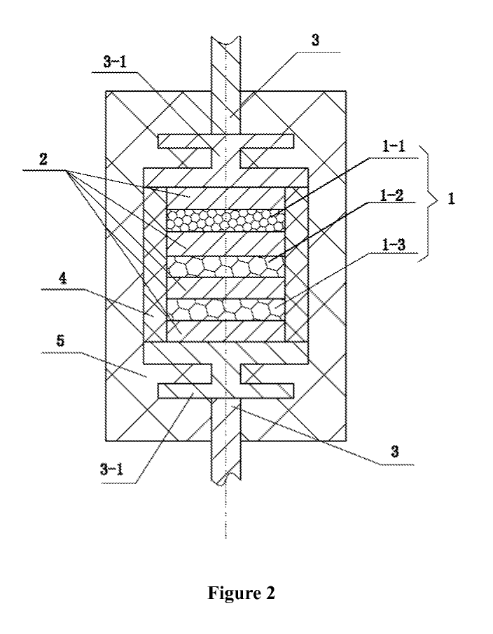

FIG. 2 is a structural representation of embodiment 2 according to the present invention. As shown in FIG. 2, the high-frequency fast recovery diode comprises a diode chipset 1, solder lugs 2, lead wires 3, lead terminals 3-1, a cladding 4, and a plastic package 5, wherein, said diode chipset 1 comprises one fast recovery diode chip 1-1 and two conventional rectifying diode chips 1-2 and 1-3. Said plastic package 5 has a cylindrical column shape. Said cladding 4 is a silicone cladding. The plastic package 5 is an epoxy resin package.

The high-frequency fast recovery diode provided in the present invention has a shorter reverse recovery time than conventional high-frequency fast recovery diodes, and it has the following reasons: presuming the charge/discharge time of fast recovery diode chip is TFR and the charge/discharge time of conventional rectifying diode chip is TRR, then TFR<TRR. For example, in the embodiment 2, the diode chipset 1 comprises one fast recovery diode chip 1-1 and two conventional rectifying diode chips 1-2 and 1-3, and its charge/discharge time is 1/TFR1+1/TRR2+1/TRR3; whereas, a conventional high-frequency fast recovery diode comprises a fast recovery diode chip solely, and its charge/discharge time is 1/TFR1+1/TFR2+1/TFR3; it is apparent 1/TFR1+1/TRR2+1/TRR3<1/TFR1+1/TFR2+1/TFR3. Therefore, the improved high-frequency fast recovery diode in the present invention has a shorter reverse recovery time characteristic than conventional high-frequency fast recovery diodes, and can shorten the reverse recovery time.

The high-frequency fast recovery diode in the present invention has higher voltage resistance than conventional high-frequency fast recovery diodes, for the following reasons: the voltage resistance rating of fast recovery diode chips available in the market is 1300V, while the voltage resistance rating of conventional rectifying diode chips at the same price available in the market is as high as 1800V. In embodiment 2, for example, the voltage resistance rating of the high-frequency fast recovery diode provided in the present invention is 1300V+2×1800V=4900V; whereas the voltage resistance rating of a conventional high-frequency fast recovery diode at the same price is 1300V×3=3900V. It is apparent that the high-frequency fast recovery diode provided in the present invention has higher voltage resistance than conventional high-frequency fast recovery diodes, namely it can improve the voltage resistance.

In the market, the price of a conventional rectifying diode chip is ⅔ of the price of a fast recovery diode chip. In embodiment 2, for example, since there is only one fast recovery diode chip among the three diode chips, with the other two fast recovery diode chips being replaced with conventional rectifying diode chips, the cost of each high-frequency fast recovery diode can be reduced by 20%. In high-frequency fast recovery diodes that comprise more diode chips, if only one chip is a fast recovery diode chip while all other chips are conventional rectifying diode chips, the production cost of such a high frequency fast recovery diode will be even lower, because conventional rectifying diode chips can be produced by the diode manufacturer from polycrystalline silicon wafers and are also available in the market, and suitable for mass production.

1. A high-frequency fast recovery diode, comprising: a diode chipset, solder lugs, lead wires, lead terminals, a cladding, and a plastic package; the diode chipset comprises n diode chips, which are aligned by equidirectional polarity; both sides of each diode chip are arranged with a solder lug and the diode chip is connected with the solder lugs; the end faces of the lead terminals of the two diode lead wires are connected with the solder lugs at both sides of the diode chipset respectively; the diode chipset and the solder lugs are enclosed by the cladding, and the two lead terminals and cladding are packed by the plastic package; wherein, among said n diode chips, 1, 2, . . . , or n−1 diode chips are fast recovery diode chips, while the rest of the diode chips are conventional rectifying diode chips.

2. The high-frequency fast recovery diode according to claim 1, wherein, said diode chipset comprises one fast recovery diode chip and two conventional rectifying diode chips.

3. The high-frequency fast recovery diode according to claim 1, wherein, said plastic package has a cylindrical or a square column shape, said cladding is a silicone cladding, and the plastic package is an epoxy resin package.

4. The high-frequency fast recovery diode according to claim 2, wherein, said plastic package has a cylindrical or a square column shape, said cladding is a silicone cladding, and the plastic package is an epoxy resin package.
